(19) United States
(12) Patent Application Publication
(10) Pub. No.: US 2024/0322526 A1
(43) Pub. Date: Sep. 26, 2024

(54) High-Power Edge-Emitting Laser Device and Manufacturing Method Thereof

(71) Applicant: CoreOptics Technology Inc., Zhunan Township (TW)

(72) Inventors: Fa-Tzu Chen, Hsinchu City (TW); Ju-Chun Cheng, Hsinchu City (TW)

(21) Appl. No.: 18/585,288

(22) Filed: Feb. 23, 2024

Related U.S. Application Data
(60) Provisional application No. 63/491,829, filed on Mar. 23, 2023.

(51) Int. Cl. H01S 5/22; H01S 5/028

(52) U.S. Cl. CPC H01S 5/22; H01S 5/0282

(57) ABSTRACT

A high-power edge-emitting laser device and a manufacturing method thereof are disclosed. The high-power edge-emitting laser device includes a substrate, a first cladding layer, an active layer, a second cladding layer, a cap layer, a passivation layer, and a dielectric layer. The first cladding layer is disposed on the substrate. The active layer is disposed on the first cladding layer. The second cladding layer is disposed on the active layer. The cap layer is disposed on the second cladding layer. The cap layer and the second cladding layer have a ridge waveguide and the ridge waveguide is a T-shape structure. The passivation layer is disposed on a luminous mesa. The dielectric layer is disposed on the passivation layer and covers a luminous facet.

### CROSS-REFERENCE TO RELATED APPLICATION

This application claims priority from U.S. Provisional Patent Application No. 63/491,829, filed on Mar. 23, 2023, in the United States Patent and Trademark Office, the content of which is hereby incorporated by reference in its entirety for all purposes.

### BACKGROUND OF THE INVENTION

### 1. Field of the Invention

The disclosure relates to a high-power edge-emitting laser device and a manufacturing method thereof, particularly to a high-power edge-emitting laser device and a manufacturing method thereof with ridge waveguide structures that may reduce manufacturing and packaging costs.

### 2. Description of the Related Art

In the application of using LEDs or vertical-cavity surface-emitting Lasers (VCSELs) as the light source, the packaging method is designed based on the characteristics of surface light emission. In contrast, an edge emitting laser is a type of laser that emits light from the side. To convert it to a surface light source, the most intuitive way is to turn the laser device 90 degrees F. or a stand-up position for use, or a reflector is placed next to the laser device, so as to deflect the side light by the reflector, which becomes surface light. However, these methods require changes in packaging methods, which are different from those of LEDs or surface-emitting lasers, thus greatly increasing the difficulty and costs of the packaging process.

In the manufacturing process of a wafer of edge-emitting laser components nowadays, the steps in general sequentially are etching ridge waveguide, forming passivation layer, forming contact electrode opening, making contact metal electrode, lapping, and making backside metal. After completion, the wafer is formed into a laser bar in a cleaving way. At this moment, the natural lattice smooth cleaving surface on both sides of the crystal strip is used as a laser luminous facet, which is then formed into a resonant cavity by facet coating. Cleaving the wafer into the laser bar is usually performed in a way of scribing and breaking, and the coating process requires stacking up the small laser bars. These two manufacturing processes are complex and time-consuming, which often greatly affect process yields.

In another manufacturing process, a luminous facet is etched first, and then the remaining hard mask is used to make patterns to etch the ridge waveguide. However, one obvious flaw of this method is that the luminous facet etched first is exposed to the environment of the subsequent etching process for the ridge waveguide, resulting in the re-etching of the formed luminous facet and making the surface quality difficult to maintain.

In this view, the existing edge-emitting laser devices and their manufacturing methods still have defects in terms of device structure and manufacturing process, making it difficult to meet the expected requirements for process efficiency and product yields. Accordingly, the inventor of the present disclosure has designed a high-power edge-emitting laser device and a manufacturing method thereof in an effort to tackle deficiencies in the prior art and further enhance the implementation and application in industries.

### SUMMARY OF THE INVENTION

In view of the aforementioned conventional problems, the purpose of the present disclosure is to provide a high-power edge-emitting laser device and a manufacturing method thereof in order to solve the problems caused by the conventional edge-emitting laser device in terms of manufacturing processes and package efficiency.

According to one purpose of the present disclosure, a high-power edge-emitting laser device is provided. The high-power edge-emitting laser device includes a substrate, a first cladding layer, an active layer, a second cladding layer, a cap layer, a passivation layer, and a dielectric layer, wherein the first cladding layer is disposed on the substrate, and the active layer is disposed on the first cladding layer. The second cladding layer is disposed on the active layer, and the cap layer is disposed on the second cladding layer, wherein the cap layer and the second cladding layer have a ridge waveguide, the ridge waveguide includes a ridge column disposed along a first direction and an extended part is disposed along a second direction perpendicular to the first direction at both ends of the ridge column, the ridge column and the extended part form a T-shape structure, so that a width of the ridge waveguide at the extended part is greater than a width of the ridge waveguide at the ridge column. The passivation layer is disposed on a luminous mesa, the luminous mesa defines a length of the active layer in the first direction, and one side of the luminous mesa exposes a luminous facet of the active layer. The dielectric layer is disposed on the passivation layer and covers the luminous facet, and a reflective plane is disposed at another end relative to the luminous facet, so that the active layer forms a resonant cavity between the luminous facet and the reflective plane, and a laser is emitted from the luminous facet.

Preferably, the ridge waveguide may extend from the second cladding layer to the active layer and the first cladding layer.

Preferably, the ridge waveguide may extend from the second cladding layer to the active layer, the first cladding layer and the substrate.

Preferably, in the first direction, a length of the ridge waveguide may be less than or equal to a length of the active layer.

Preferably, the ridge waveguide may include a plurality of ridge waveguide structures disposed side by side in the second direction, and the extended parts of the plurality of ridge waveguide structures are connected to each other to form an extended structure.

Preferably, the high-power edge-emitting laser device may further include a reflected metal layer. The reflected metal layer is disposed on a reflector made by etching an epitaxy and the substrate, a bevel of the reflected metal layer faces the luminous facet, and there is a horizontal distance between a top of the reflected metal layer and the luminous facet.

Preferably, a height of the top of the reflected metal layer may be higher than a height of the luminous facet, and the horizontal distance is less than 12 times a depth of the active layer.

Preferably, a groove may be disposed between the bevel of the reflected metal layer and the luminous facet.

Preferably, the reflected metal layer may include Ti/Al, Cr/Al, Cr/Au, Ni/Al, Ni/Au, AuGe/Au, or AuGe/Ni/Au.

Preferably, the high-power edge-emitting laser device further includes a metallic film, wherein the metallic film is disposed on part of the dielectric layer and covers the reflective plane, and the metallic film may contact the cap layer through an opening.

Preferably, the metallic film includes Ti/Au, Ti/Al, Cr/Al, Cr/Au, Ni/Al, Ni/Au, or Au.

According to one purpose of the present disclosure, a manufacturing method of a high-power edge-emitting laser device is provided. The manufacturing method includes the following steps: disposing a substrate and sequentially forming a first cladding layer, an active layer, a second cladding layer, and a cap layer on the substrate; etching the cap layer and the second cladding layer to form a ridge waveguide, wherein the ridge waveguide comprises a ridge column formed along a first direction and an extended part formed at both ends of the ridge column along a second direction perpendicular to the first direction, the ridge column and the extended part form a T-shape structure; etching the ridge waveguide to form a luminous mesa and disposing a passivation layer on the luminous mesa, the luminous mesa defines a length of the active layer in the first direction, and the luminous mesa exposes a luminous facet of the active layer; disposing a dielectric layer on the passivation layer and the luminous facet and forming a reflective plane at another end relative to the luminous facet, wherein a resonant cavity is formed between the luminous facet and the reflective plane.

Preferably, the active layer and the first cladding layer may be further etched when the cap layer and the second cladding layer are etched, so that the ridge waveguide extends from the second cladding layer to the active layer and the first cladding layer.

Preferably, the active layer, the first cladding layer, and the substrate may be further etched when the cap layer and the second cladding layer are etched, so that the ridge waveguide extends from the second cladding layer to the active layer, the first cladding layer, and the substrate.

Preferably, in the first direction, a length of the ridge waveguide may be less than or equal to a length of the active layer.

Preferably, the ridge waveguide may include a plurality of ridge waveguide structures disposed side by side in the second direction, and the extended parts of the plurality of ridge waveguide structures are connected to each other to form an extended structure.

Preferably, the manufacturing method of the high-power edge-emitting laser device may further form a reflective bevel by etching the first cladding layer, the active layer, the second cladding layer, and the substrate with a mask having a predetermined slope, and form a reflected metal layer on the reflective bevel, wherein a bevel of the reflected metal layer faces the luminous facet, and there is a horizontal distance between a top of the reflected metal layer and the luminous facet.

Preferably, a height of the top of the reflected metal layer may be higher than a height of the luminous facet, and the horizontal distance is less than 12 times a depth of the active layer.

Preferably, a groove may be formed between a bevel of the reflected metal layer and the luminous facet.

Preferably, the reflected metal layer may include Ti/Al, Cr/Al, Cr/Au, Ni/Al, Ni/Au, AuGe/Au, or AuGe/Ni/Au.

Preferably, the manufacturing method of the high-power edge-emitting laser device may further etch the passivation layer and the dielectric layer to form an opening, wherein the opening exposes the cap layer, and a metallic film is disposed on part of the dielectric layer and covers the reflective plane, the metallic film contacts the cap layer through the opening.

Preferably, the metallic film may include Ti/Au, Ti/Al, Cr/Al, Cr/Au, Ni/Al, Ni/Au, or Au.

As stated, the high-power edge-emitting laser device and the manufacturing method thereof according to the present disclosure may have one or more of the following advantages:

(1) The high-power edge-emitting laser device and the manufacturing method thereof may prevent the etching process from affecting the production quality of the end face of the ridge waveguide in the process of manufacturing the luminous facet through the T-shape ridge waveguide structure. The poor facet would further affect the distribution of current flow to the resonant cavity, leading to poor luminous efficiency of the device which reduces product yields.

(2) The high-power edge-emitting laser device and the manufacturing method thereof may prevent the etching process during the production of the ridge waveguide from affecting the quality of the luminous facet by producing the ridge waveguide first and then proceeding to the production of the luminous facet. Moreover, through the disposition of multiple ridge waveguide structures, the amount of disposition space required for the device may be reduced; meanwhile, the defective rate caused by etching may be reduced via the interconnected extended structures.

(3) The high-power edge-emitting laser device and the manufacturing method thereof may improve the luminous efficiency of the resonant cavity by covering the end face of the active layer with the production of a metallic film by way of coating to form a reflective plane. Moreover, through the disposition of the reflected metal layer, the edge-emitting laser device is converted into a surface-emitting laser device, thus increasing the variety of the device and reducing the steps for the package process in order to save the production costs.

### BRIEF DESCRIPTION OF THE DRAWINGS

To make the technical features, content, and advantages of the present disclosure and the achievable effects more obvious, the present disclosure is described in detail together with the drawings and in the form of expressions of the embodiments as follows:

FIG. 1A, FIG. 1B, and FIG. 1C are schematic diagrams of the high-power edge-emitting laser device according to the first embodiment of the present disclosure.

FIG. 2A, FIG. 2B, and FIG. 2C are schematic diagrams of the high-power edge-emitting laser device according to the second embodiment of the present disclosure.

FIG. 3A, FIG. 3B, and FIG. 3C are schematic diagrams of the high-power edge-emitting laser device according to the third embodiment of the present disclosure.

FIG. 4A, FIG. 4B, and FIG. 4C are schematic diagrams of the high-power edge-emitting laser device according to the fourth embodiment of the present disclosure.

FIG. 5A and FIG. 5B are schematic diagrams of the peripheral structure of the high-power edge-emitting laser device according to an embodiment of the present disclosure.

FIG. 6A, FIG. 6B and FIG. 6C are schematic diagrams of multiple ridge waveguide structures according to an embodiment of the present disclosure.

FIG. 7A to FIG. 7K are schematic diagrams of the manufacturing method of the high-power edge-emitting laser device according to the first embodiment and the second embodiment of the present disclosure.

FIG. 8A to FIG. 8G are schematic diagrams of the manufacturing method of the high-power edge-emitting laser device according to the third embodiment of the present disclosure.

FIG. 9A to FIG. 9F are schematic diagrams of the manufacturing method of metallic contact according to an embodiment of the present disclosure.

### DESCRIPTION OF THE PREFERRED EMBODIMENTS

To illustrate the technical features, contents, advantages, and achievable effects of the present disclosure, the embodiments together with the accompanying drawings are described in detail as follows. However, the drawings are used only for the purpose of indicating and supporting the specification, which is not necessarily the real proportion and precise configuration after the implementation of the present disclosure. Therefore, the relations of the proportion and configuration of the accompanying drawings should not be interpreted to limit the actual scope of implementation of the present disclosure.

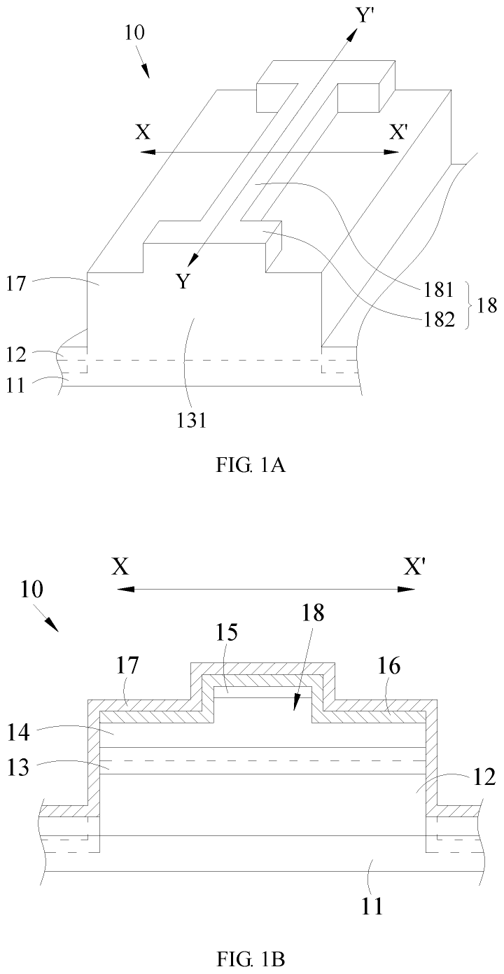

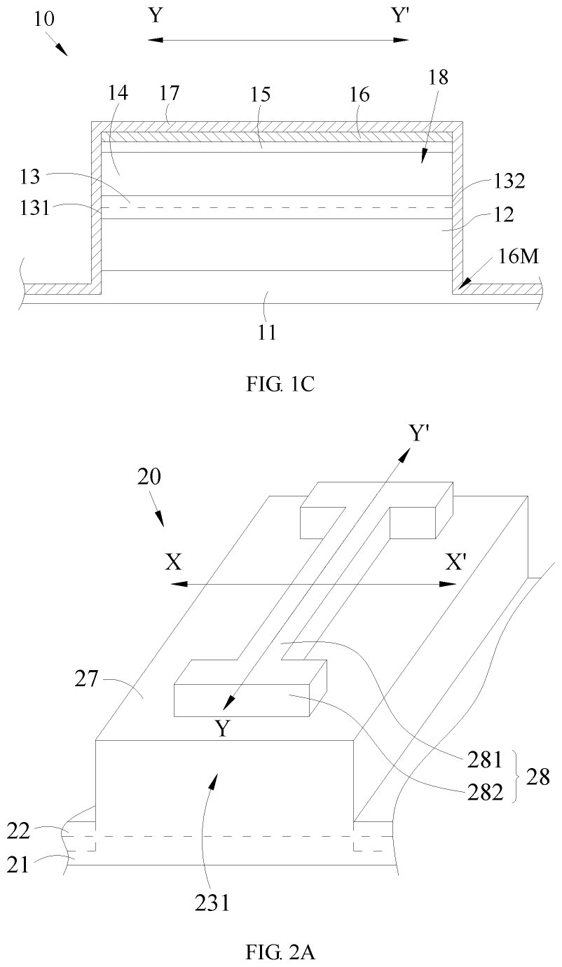

Please refer to FIG. 1A, FIG. 1B, and FIG. 1C, which are schematic diagrams of the high-power edge-emitting laser device according to the first embodiment of the present disclosure, wherein FIG. 1A is a three-dimensional schematic diagram of the high-power edge-emitting laser device 10, FIG. 1B is a cross-sectional schematic diagram along the direction of line segment XX′ in FIG. 1A, and FIG. 1C is a cross-sectional schematic diagram along the direction of line segment YY′ in FIG. 1A. As shown in the figures, the high-power edge-emitting laser device 10 includes a substrate 11, a first cladding layer 12, an active layer 13, a second cladding layer 14, a cap layer 15, a passivation layer 16, and a dielectric layer 17. The substrate 11 may be a doped III-V compound, such as GaAs/InP/GaN. The first cladding layer 12, the active layer 13, the second cladding layer 14, and the cap layer 15 are sequentially formed on the substrate 11 through the metal-organic chemical vapor deposition (MOCVD) or a molecular beam epitaxy (MBE) machine. The materials of the first cladding layer 12, the second cladding layer 14, and the cap layer 15 may be the same or different materials, such as AlGaAs, InP, AlₓGa_{y}InP, InGaAs, InGaAsP, Nitride (AlN), AlSb, GaAs, AlAs, GaSb, AlGaSb, or superlattice formed thereof.

The active layer 13 is sandwiched between the first cladding layer 12 and the second cladding layer 14, which is an active region formed of a luminescent material with a bandgap, wherein the luminescent material may include AlGaN, AlGaInP/GaAs, GaxInyP/GaAs, GaAlAs/GaAs, GaAs/GaAs, InGaAs/GaAs, InGaAsP/GaAs, InGaAsP/InP, InGaAsSb, PbCds, GaInN, ZnSSe, ZnCdSe, PbSSe, PbSnTe, PbSnSe, or combinations thereof, either as a single layer or as a combination of multi-layer materials. The cap layer 15 and the second cladding layer 14 may be etched to form a ridge waveguide 18 structure as shown in the figures, the ridge waveguide 18 includes a ridge column 181 formed along a first direction (the Y direction as shown in the figures), an extended part 182 is disposed along a second direction perpendicular to the first direction (the X direction as shown in the figures) at both ends of the ridge column 181, the ridge column 181 and the extended part 182 form a T-shape structure at both ends of the ridge column 181, so that a width of the ridge waveguide 18 at the extended part 182 is greater than a width at the ridge column 181. Without the disposition of the extended part 182, when etching is performed to form the end face such as the ridge waveguide 18 or the luminous facet 131 or the reflective plane 132 of the active layer 13, the end face of the ridge column 181 close to the end face of the active layer 13 is etched to recede. Alternatively, the width of the end face of the ridge column 181 is smaller than the width of the ridge column 181. When the current flows through the ridge waveguide 18, the current density and uniformity will be reduced, so as to affect the luminous efficiency. Therefore, the disposition of the ridge waveguide 18 with a T-shape structure may avoid affecting the quality of the end face of the ridge waveguide 18 when etching is performed to form the end face such as the ridge waveguide 18 or the luminous facet 131 or the reflective plane 132 with the active layer 13.

The passivation layer 16 is disposed on the luminous mesa 16M, and the luminous mesa 16M defines a length of the active layer 13 in the first direction, that is, forming a stepped-like mesa structure at both ends by etching the structure at both ends of the ridge waveguide 18, as well as forming the luminous facet 131 of the active layer 13 by exposing the end face of the active layer 13. The passivation layer 16 is disposed on the second cladding layer 14 and the cap layer 15, and the passivation layer 16 may include dielectric materials such as oxides, fluorides, ceramics, silicon carbide, and the like, for example, silicon dioxide (SiO₂) or silicon nitride (SiₓN_{y}). The dielectric layer 17 is disposed on the passivation layer 16 and covers the end face of the active layer 13; in the present embodiment, the dielectric layer 17 is a thin film of dielectric material coated on the end faces of the entire passivation layer 16 and the active layer 13, which is used as an anti-reflective (AR coating) thin film, that is, covering the end face of the active layer 13 with an anti-reflective or low-reflective film as the luminous facet 131. Then, a metallic film with high reflectivity is formed on another end face with the use of the lift-off manufacturing process, so that another end face becomes a reflective plane 132 with high reflectivity. The structure of the metallic film is to be further illustrated in the following embodiments. The active layer 13 forms a resonant cavity between the luminous facet 131 and the reflective plane 132, and when the current flows to the resonant cavity along the ridge waveguide 18, the active layer 13 may emit a laser from the luminous facet 131 in the first direction (the Y direction as shown in the figures).

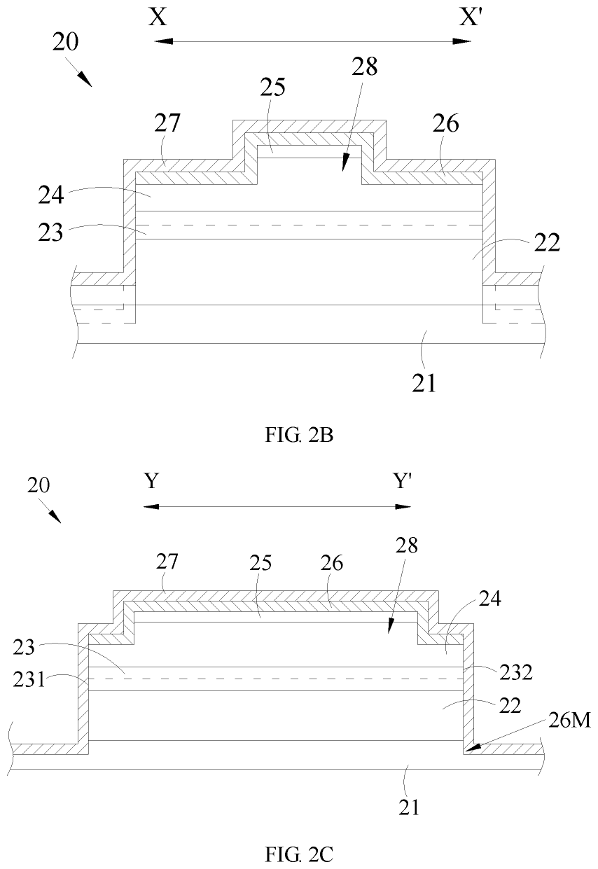

Please refer to FIG. 2A, FIG. 2B, and FIG. 2C, which are schematic diagrams of the high-power edge-emitting laser device according to the second embodiment of the present disclosure, wherein FIG. 2A is a three-dimensional schematic diagram of the high-power edge-emitting laser device 20, FIG. 2B is a cross-sectional schematic diagram along the direction of line segment XX′ in FIG. 2A, and FIG. 2C is a cross-sectional schematic diagram along the direction of line segment YY′ in FIG. 2A. As shown in the figures, the high-power edge-emitting laser device 20 includes a substrate 21, a first cladding layer 22, an active layer 23, a second cladding layer 24, a cap layer 25, a passivation layer 26, and a dielectric layer 27. The substrate 21 may be a doped III-V compound, such as GaAs/InP/GaN. The first cladding layer 22, the active layer 23, the second cladding layer 24, and the cap layer 25 are sequentially formed on the substrate 21 through the metal-organic chemical vapor deposition (MOCVD) or a molecular beam epitaxy (MBE) machine. The materials of the first cladding layer 22, the second cladding layer 24, and the cap layer 25 may be the same or different materials, such as AlGaAs, InP, AlₓGa_{y}InP, InGaAs, InGaAsP, Nitride (AlN), AlSb, GaAs, AlAs, GaSb, AlGaSb, or superlattice formed thereof.

The active layer 23 is sandwiched between the first cladding layer 22 and the second cladding layer 24, which is an active region formed of a luminescent material with a bandgap, wherein the luminescent material may include AlGaN, AlGaInP/GaAs, GaₓIn_{y}P/GaAs, GaAlAs/GaAs, GaAs/GaAs, InGaAs/GaAs, InGaAsP/GaAs, InGaAsP/InP, InGaAsSb, PbCds, GalnN, ZnSSe, ZnCdSe, PbSSe, PbSnTe, PbSnSe, or combinations thereof, either as a single layer or as a combination of multi-layer materials. The cap layer 25 and the second cladding layer 24 may be etched to form a ridge waveguide 28 structure as shown in the figures, the ridge waveguide 28 includes a ridge column 281 formed along a first direction (the Y direction as shown in the figures), an extended part 282 is disposed along a second direction perpendicular to the first direction (the X direction as shown in the figures) at both ends of the ridge column 281, and the ridge column 281 and the extended part 282 form a T-shape structure at both ends of the ridge column 281, so that a width of the ridge waveguide 28 at the extended part 282 is greater than a width at the ridge column 281. Similar to the previous embodiment, the disposition of the ridge waveguide 28 with a T-shape structure may avoid affecting the quality of the end face of the ridge waveguide 28 when etching is performed to form the end face such as the ridge waveguide 28 or the luminous facet 231 or the reflective plane 232 with the active layer 23. Different from the previous embodiment, in the present embodiment, in the first direction, the length of the ridge waveguide 28 may be smaller than the length of the active layer 23, and forming a stepped-like appearance in the second cladding layer 24.

Since the length of the ridge waveguide 28 is smaller than the length of the active layer 23, in the manufacturing of the luminous mesa 26M, only both ends of the second cladding layer 24 are etched to form a stepped-like mesa, that is, etching the second cladding layer 24, the active layer 23, the first cladding layer 22, and the substrate 21 at both ends to form a stepped-like mesa structure without etching the ridge waveguide 28. After the completion of the production of the luminous mesa 26M, the passivation layer 26 is disposed on the second cladding layer 24 and the cap layer 25, and the length of the active layer 23 in the first direction is still greater than the length of the ridge waveguide 28. The passivation layer 26 may include dielectric materials such as oxides, fluorides, ceramics, silicon carbide, and the like, for example, silicon dioxide (SiO₂) or silicon nitride (SiₓN_{y}). The dielectric layer 27 is disposed on the passivation layer 26 and covers the end face of the active layer 23; in the present embodiment, the dielectric layer 27 is a thin film of dielectric material coated on the end faces of the entire passivation layer 26 and the active layer 23, which is used as an anti-reflective (AR coating) thin film, that is, covering the end face of the active layer 23 with an anti-reflective or low-reflective film as the luminous facet 231. Then, a metallic film with high reflectivity is formed on another end face with the use of the lift-off manufacturing process, so that another end face becomes a reflective plane 232 with high reflectivity. The structure of the metallic film is to be further illustrated in the following embodiments. The active layer 23 forms a resonant cavity between the luminous facet 231 and the reflective plane 232, and when the current flows to the resonant cavity along the ridge waveguide 28, the active layer 23 may emit a laser from the luminous facet 231 in the first direction (the Y direction as shown in the figures).

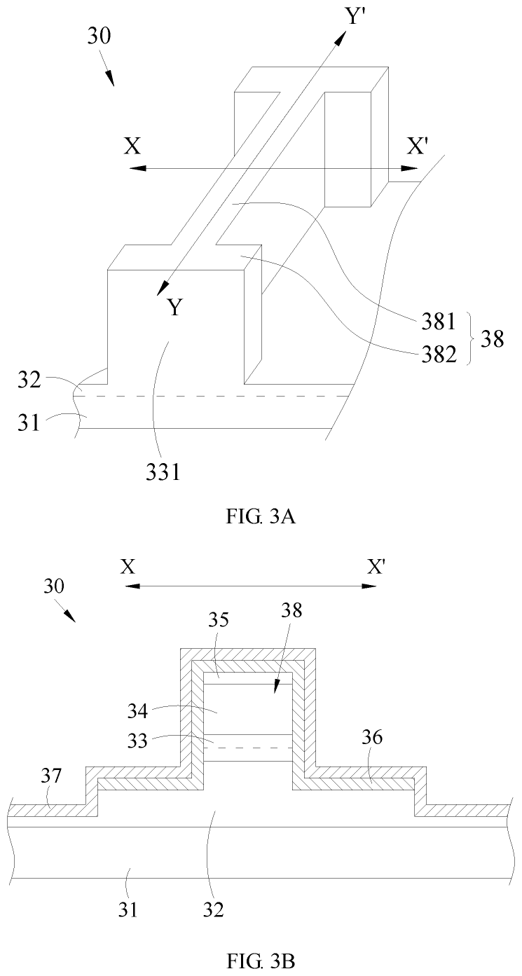

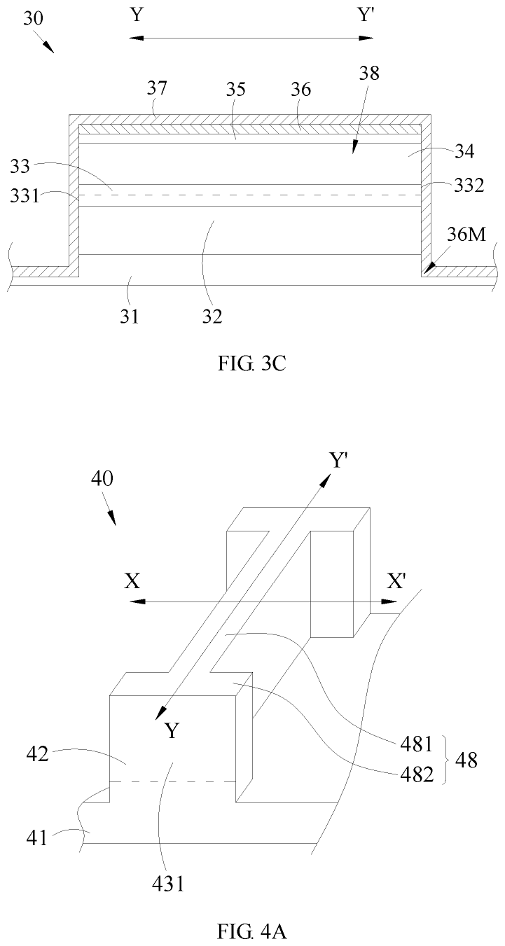

Please refer to FIG. 3A, FIG. 3B, and FIG. 3C, which are schematic diagrams of the high-power edge-emitting laser device according to the third embodiment of the present disclosure, wherein FIG. 3A is a three-dimensional schematic diagram of the high-power edge-emitting laser device 30, FIG. 3B is a cross-sectional schematic diagram along the direction of line segment XX′ in FIG. 3A, and FIG. 3C is a cross-sectional schematic diagram along the direction of line segment YY′ in FIG. 3A. As shown in the figures, the high-power edge-emitting laser device 30 includes a substrate 31, a first cladding layer 32, an active layer 33, a second cladding layer 34, a cap layer 35, a passivation layer 36, and a dielectric layer 37. The substrate 31 may be a doped III-V compound, such as GaAs/InP/GaN. The first cladding layer 32, the active layer 33, the second cladding layer 34, and the cap layer 35 are sequentially formed on the substrate 31 through the metal-organic chemical vapor deposition (MOCVD) or a molecular beam epitaxy (MBE) machine. The materials of the first cladding layer 32, the second cladding layer 34, and the cap layer 35 may be the same or different materials, such as AlGaAs, InP, AlₓGa_{y}InP, InGaAs, InGaAsP, Nitride (AlN), AlSb, GaAs, AlAs, GaSb, AlGaSb, or superlattice formed thereof.

The active layer 33 is sandwiched between the first cladding layer 32 and the second cladding layer 34, which is an active region formed of a luminescent material with a bandgap, wherein the luminescent material may include AlGaN, AlGalnP/GaAs, GaₓIn_{y}P/GaAs, GaAlAs/GaAs, GaAs/GaAs, InGaAs/GaAs, InGaAsP/GaAs, InGaAsP/InP, InGaAsSb, PbCds, GaInN, ZnSSe, ZnCdSe, PbSSe, PbSnTe, PbSnSe, or combinations thereof, either as a single layer or as a combination of multi-layer materials. What is different from the previous embodiment is that the cap layer 35, the second cladding layer 34, the active layer 33, and the first cladding layer 32 may be etched to form a ridge waveguide 38 structure as shown in the figures, the ridge waveguide 38 includes a ridge column 381 formed along a first direction (the Y direction as shown in the figures), an extended part 382 is disposed along a second direction perpendicular to the first direction (the X direction as shown in the figures) at both ends of the ridge column 381, and the ridge column 381 and the extended part 382 form a T-shape structure, so that a width of the ridge waveguide 38 at the extended part 382 is greater than a width at the ridge column 381. Similar to the previous embodiment, the disposition of the ridge waveguide 38 with a T-shape structure may avoid affecting the quality of the end face of the ridge waveguide 38 when etching is performed to form the end face such as the ridge waveguide 38 or the luminous facet 331 or the reflective plane 332 with the active layer 33. In the present embodiment, the depth of the ridge waveguide 38 may extend downward from the original second cladding layer 34 to the active layer 33 and the first cladding layer 32; that is, the etching continues to the etching depth below the active layer 33.

The passivation layer 36 is disposed on the luminous mesa 36M, and the luminous mesa 36M defines a length of the active layer 33 in the first direction, that is, forming a stepped-like mesa structure at both ends by etching the structure at both ends of the ridge waveguide 38, as well as forming the luminous facet 331 of the active layer 33 by exposing the end face of the active layer 33. The passivation layer 36 is disposed on the first cladding layer 32 and the cap layer 35, and the passivation layer 36 may include dielectric materials such as oxides, fluorides, ceramics, silicon carbide, and the like, for example, silicon dioxide (SiO₂) or silicon nitride (SiₓN_{y}). The dielectric layer 37 is a thin film of dielectric material coated on the end faces of the entire passivation layer 36 and the active layer 33, which is used as an anti-reflective (AR coating) thin film, that is, covering the end face of the active layer 33 with an anti-reflective or low-reflective film as the luminous facet 331. Then, a metallic film with high reflectivity is formed on another end face with the use of the lift-off manufacturing process, so that another end face becomes a reflective plane 332 with high reflectivity. The active layer 33 forms a resonant cavity between the luminous facet 331 and the reflective plane 332, and when the current flows to the resonant cavity along the ridge waveguide 38, the active layer 33 may emit a laser from the luminous facet 331 in the first direction (the Y direction as shown in the figures).

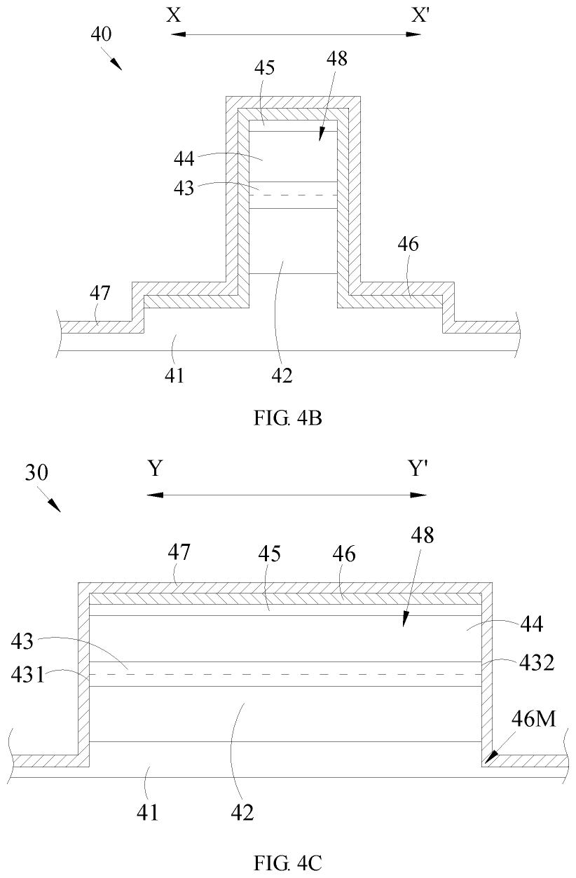

Please refer to FIG. 4A, FIG. 4B, and FIG. 4C, which are schematic diagrams of the high-power edge-emitting laser device according to the fourth embodiment of the present disclosure, wherein FIG. 4A is a three-dimensional schematic diagram of the high-power edge-emitting laser device 40, FIG. 4B is a cross-sectional schematic diagram along the direction of line segment XX′ in FIG. 4A, and FIG. 4C is a cross-sectional schematic diagram along the direction of line segment YY′ in FIG. 4A. As shown in the figures, the high-power edge-emitting laser device 40 includes a substrate 41, a first cladding layer 42, an active layer 43, a second cladding layer 44, a cap layer 45, a passivation layer 46, and a dielectric layer 47. The substrate 41 may be a doped III-V compound, such as GaAs/InP/GaN. The first cladding layer 42, the active layer 43, the second cladding layer 44, and the cap layer 45 are sequentially formed on the substrate 41 through the metal-organic chemical vapor deposition (MOCVD) or a molecular beam epitaxy (MBE) machine. The materials of the first cladding layer 42, the second cladding layer 44, and the cap layer 45 may be the same or different materials, such as AlGaAs, InP, AlₓGa_{y}InP, InGaAs, InGaAsP, Nitride (AlN), AlSb, GaAs, AlAs, GaSb, AlGaSb, or superlattice formed thereof.

The active layer 43 is sandwiched between the first cladding layer 42 and the second cladding layer 44, which is an active region formed of a luminescent material with a bandgap, wherein the luminescent material may include AlGaN, AlGalnP/GaAs, GaₓIn_{y}P/GaAs, GaAlAs/GaAs, GaAs/GaAs, InGaAs/GaAs, InGaAsP/GaAs, InGaAsP/InP, InGaAsSb, PbCds, GaInN, ZnSSe, ZnCdSe, PbSSe, PbSnTe, PbSnSe, or combinations thereof, either as a single layer or as a combination of multi-layer materials. What is different from the previous embodiment is that the cap layer 45, the second cladding layer 44, the active layer 43, the first cladding layer 42, and the substrate 41 may be etched to form a ridge waveguide 48 structure as shown in the figures, the ridge waveguide 48 includes a ridge column 481 formed along a first direction (the Y direction as shown in the figures), an extended part 482 is disposed along a second direction perpendicular to the first direction (the X direction as shown in the figures) at both ends of the ridge column 481, and the ridge column 481 and the extended part 482 form a T-shape structure, so that a width of the ridge waveguide 48 at the extended part 482 is greater than a width at the ridge column 481. Similar to the previous embodiment, the disposition of the ridge waveguide 48 with a T-shape structure may avoid affecting the quality of the end face of the ridge waveguide 48 when etching is performed to form the end face such as the ridge waveguide 48 or the luminous facet 431 or the reflective plane 432 with the active layer 43. In the present embodiment, the depth of the ridge waveguide 48 may extend downward from the original second cladding layer 44 to the substrate 41; that is, the etching continues to the etching depth below the active layer 43.

The passivation layer 46 is disposed on the luminous mesa 46M, and the luminous mesa 46M defines a length of the active layer 43 in the first direction, that is, forming a stepped-like mesa structure at both ends by etching the structure at both ends of the ridge waveguide 48, as well as forming the luminous facet 431 of the active layer 43 by exposing the end face of the active layer 43. The passivation layer 46 is disposed on the substrate 41 and the cap layer 45, and the passivation layer 46 may include dielectric materials such as oxides, fluorides, ceramics, silicon carbide, and the like, for example, silicon dioxide (SiO₂) or silicon nitride (SiₓN_{y}). The dielectric layer 47 is a thin film of dielectric material coated on the end faces of the entire passivation layer 46 and the active layer 43, which is used as an anti-reflective (AR coating) thin film, that is, covering the end face of the active layer 43 with an anti-reflective or low-reflective film as the luminous facet 431. Then, a metallic film with high reflectivity is formed on another end face with the use of the lift-off manufacturing process, so that another end face becomes a reflective plane 432 with high reflectivity. The active layer 43 forms a resonant cavity between the luminous facet 431 and the reflective plane 432, and when the current flows to the resonant cavity along the ridge waveguide 48, the active layer 43 may emit a laser from the luminous facet 431 in the first direction (the Y direction as shown in the figures).

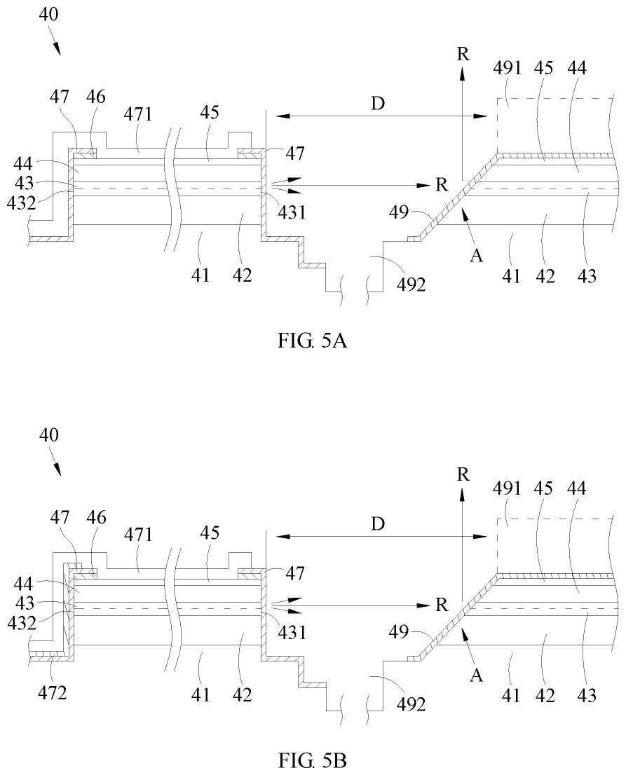

Please refer to FIG. 5A and FIG. 5B, which are schematic diagrams of the peripheral structure of the high-power edge-emitting laser device according to yet another embodiment of the present disclosure. The high-power edge-emitting laser device 40 includes a substrate 41, a first cladding layer 42, an active layer 43, a second cladding layer 44, a cap layer 45, a passivation layer 46, and a dielectric layer 47. The substrate 41 may be a doped III-V compound. The first cladding layer 42, the active layer 43, the second cladding layer 44, and the cap layer 45 are sequentially formed on the substrate 41 through the metal-organic chemical vapor deposition (MOCVD) or a molecular beam epitaxy (MBE) machine. The cap layer 45, the second cladding layer 44, the active layer 43, the first cladding layer 42, and the substrate 41 are etched, and the structures of the ridge waveguide luminous mesa 46M and the end face are produced. The protective layer 46 is disposed on the luminous mesa 46M, and the dielectric layer 47 is disposed on the passivation layer 46 and the end face of the active layer 43. For the materials and structures of the substrate 41, the first cladding layer 42, the active layer 43, the second cladding layer 44, the cap layer 45, the passivation layer 46, and the dielectric layer 47, please refer to the previous embodiments, and the same content shall not be described repeatedly.

In FIG. 5A, the dielectric layer 47 is a thin film of dielectric material coated on the end faces of the entire passivation layer 46 and the active layer 43, which is used as an anti-reflective (AR coating) thin film, that is, covering the end face of the active layer 43 with an anti-reflective or low-reflective film as the luminous facet 431. Then, the openings of the dielectric layer 47 and the passivation layer 46 are produced, and the first metallic film 471 with high reflectivity is formed on the openings and the reflective plane 432 with the use of the lift-off manufacturing process, so that another end face of the luminous facet 431 becomes a reflective plane 432 with high reflectivity, and the first metal film 471 is in contact with the cap layer 45 and serves as an electrode contact for supplying electrical energy. The active layer 43 forms a resonant cavity between the luminous facet 431 and the reflective plane 432, and when the current flows to the resonant cavity along the ridge waveguide, the active layer 43 may emit a laser R from the luminous facet 431. The metallic material of the first metallic film 471 may include Ti/Au, Ti/Al, Cr/Al, Cr/Au, Ni/Al, Ni/Au, or Au.

In another embodiment of FIG. 5B, the dielectric layer 47 is a thin film of dielectric material coated on the end faces of the entire passivation layer 46 and the active layer 43, which is used as an anti-reflective (AR coating) thin film, that is, covering the end face of the active layer 43 with an anti-reflective or low-reflective film as the luminous facet 431. What is different from the previous embodiment is that on another end face relative to the luminous facet 431, the second metallic film 472 with high reflectivity is firstly formed with the use of the lift-off manufacturing process, and the reflective plane 432 is formed with the second metallic film covering the end face. The active layer 43 forms a resonant cavity between the luminous facet 431 and the reflective plane 432, and when the current flows to the resonant cavity along the ridge waveguide, the active layer 43 may emit a laser R from the luminous facet 431. Then, the openings of the dielectric layer 47 and the passivation layer 46 are produced, and a similar first metallic film 471 is formed on the openings and the reflective plane 432 with the use of the lift-off manufacturing process, so that the first metallic film 471 is in contact with the cap layer 45 and serves as an electrode contact for supplying electrical energy. The first metallic film 471 may cover or not cover the second metallic film 472. The active layer 43 forms a resonant cavity between the luminous facet 431 and the reflective plane 432, and when the current flows to the resonant cavity along the ridge waveguide, the active layer 43 may emit a laser R from the luminous facet 431. The metallic material of the second metallic film 472 includes Ti/Au, Ti/Al, Cr/Al, Cr/Au, Ni/Al, Ni/Au, or Au, and the second metallic film 472 and the first metallic film 471 may choose the same or different metallic materials.

The reflected metal layer 49 is further disposed on a side corresponding to the luminous facet 431. For the reflected metal layer 49, the semiconductor structures of the substrate 41, the first cladding layer 42, the active layer 43, the second cladding layer 44, and the cap layer 45 may be etched through a mask having a predetermined slope, so as to form a reflective bevel A thereon. The reflected metal layer 49 is formed on the reflective bevel A, so that the bevel of the reflected metal layer 49 faces the luminous facet 431, and the laser R emitted from the luminous facet 431 may be changed from the horizontal direction to the vertical direction after being reflected by the reflected metal layer 49. The original edge-emitting laser R is changed to a surface-emitting laser R without significantly changing the semiconductor package structure. The metallic material of the reflected metal layer 49 may include Ti/Al, Cr/Al, Cr/Au, Ni/Al, Ni/Au, AuGe/Au, or AuGe/Ni/Au.

Since the laser beam has a certain divergent angle, the closer the reflective plane of the reflected metal layer 49 is to the luminous facet 431, or the lower the position of the active layer 43, the greater the light power may be deflected. In the present embodiment, there is a horizontal distance D between the top of the reflected metal layer 49 and the luminous facet 431, and the horizontal distance D may be less than 12 times the depth of the active layer 43 (that is, the distance from the wafer surface to the active layer 43). In addition, the width of the reflected metal layer 49 needs to be larger than the width of the ridge waveguide in order to obtain sufficient optical power transition. To further increase the optical power, the height 491 of the reflected metal layer 49 may be increased, so that the height of the top of the reflected metal layer 49 is higher than the height of the luminous facet 431. In the etching process, the groove 492 is formed between the bevel A of the reflected metal layer 49 and the luminous facet 431, the groove 492 may trap part of the laser R that is emitted obliquely downward at a larger angle, and in a sensing application where laser R is used as a light source, noise may be reduced and the signal-to-noise ratio (SNR) may be increased.

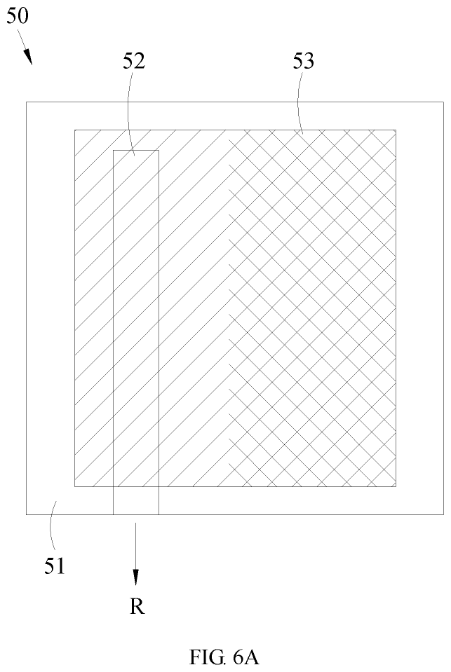

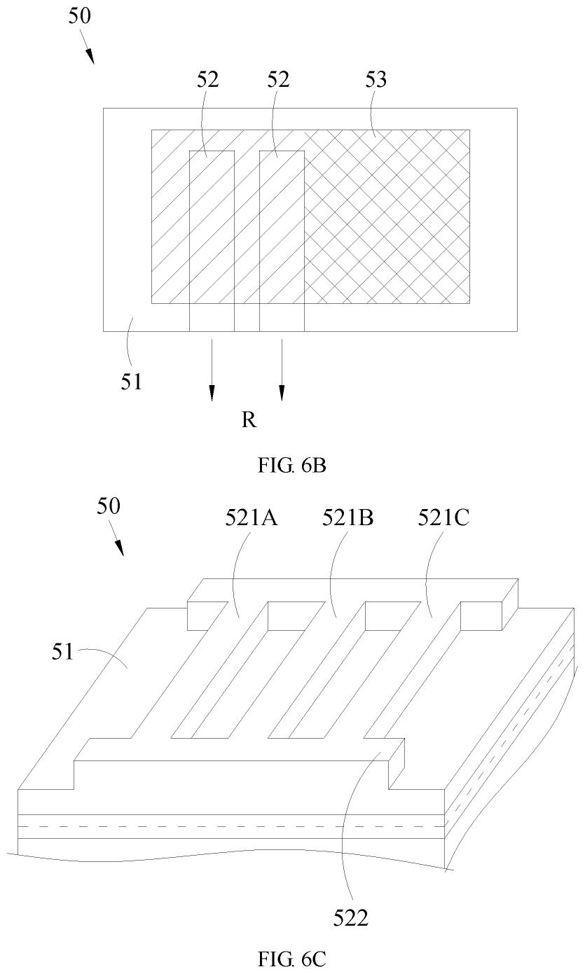

Please refer to FIG. 6A, FIG. 6B, and FIG. 6C, which are schematic diagrams of multiple ridge waveguide structures according to an embodiment of the present disclosure, wherein FIG. 6A is a plane schematic diagram of lengthening the ridge waveguide structure in order to increase the output power based on the conventional technique, FIG. 6B is a plane schematic diagram of multiple ridge waveguide structures according to the present disclosure, and FIG. 6C is a schematic diagram of multiple ridge waveguide structures and extended structures. As shown in FIG. 6A, an increase in the output power of the edge-emitting laser device 50 is generally achieved by increasing the length h of the ridge waveguide 52. Since the bond pad 53 of the wafer 51 is generally located next to the ridge waveguide 52, increasing the length h of the ridge waveguide 52 will also increase the length of the bond pad 53. This design results in part of the bond pad 53 being left idle, wasting a lot of size and area of chip, so as to decrease the quantity of chip generated. In the present embodiment, as shown in FIG. 6B, multiple ridge waveguides 52 are placed side by side to achieve the purpose of increasing output power, and the size and area of chip are slightly increased by utilizing appropriate space for the bond pad. For example, a long ridge waveguide 52 with a length of h may be divided into two ridge waveguides 52 with a length of 0.5 h for disposition, resulting in a significant reduction in the size and area of chip. The ridge waveguide 52 may also be disassembled into more strips to make the length of each ridge waveguide 52 shorter, with the shortest length determined by the smallest required bond pad 53.

As shown in FIG. 6C, the ridge waveguide 52 may include a first ridge column 521A, a second ridge column 521B, and a third ridge column 521C, and the number disposed is determined according to the power requirements and the area of the bond pad 53. These ridge waveguides 52 may also be disposed with extended parts on the end face of the luminous facet to form a T-shape structure, and the extended parts of the plurality of ridge waveguide 52 structures may be connected to each other to form an extended structure 522. Connecting the extended parts together may prevent the formation of poor end faces of the ridge waveguide 52 at each individual extended part, and moving the defective areas to both ends of the extended structures may reduce the incidence of defective end faces during the etching process.

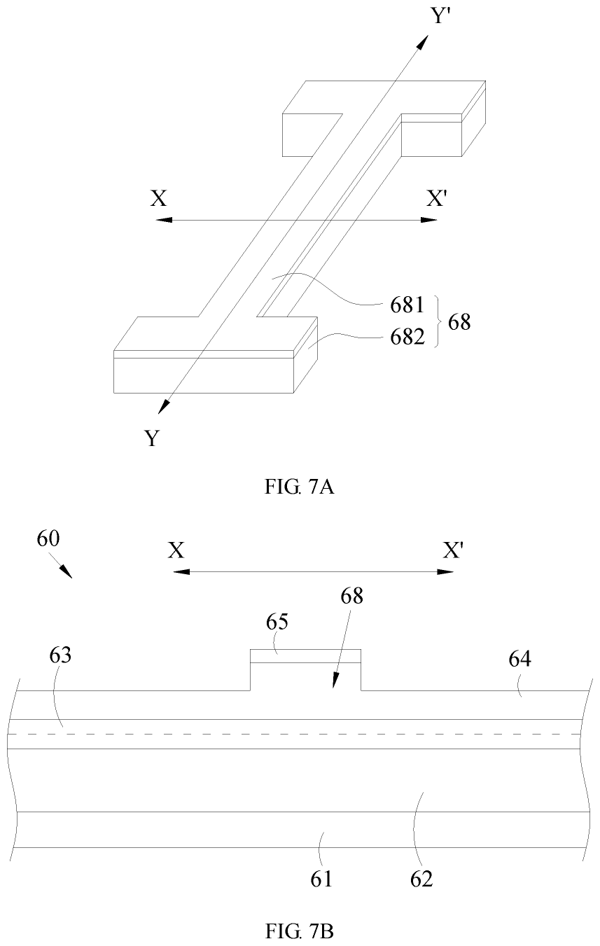

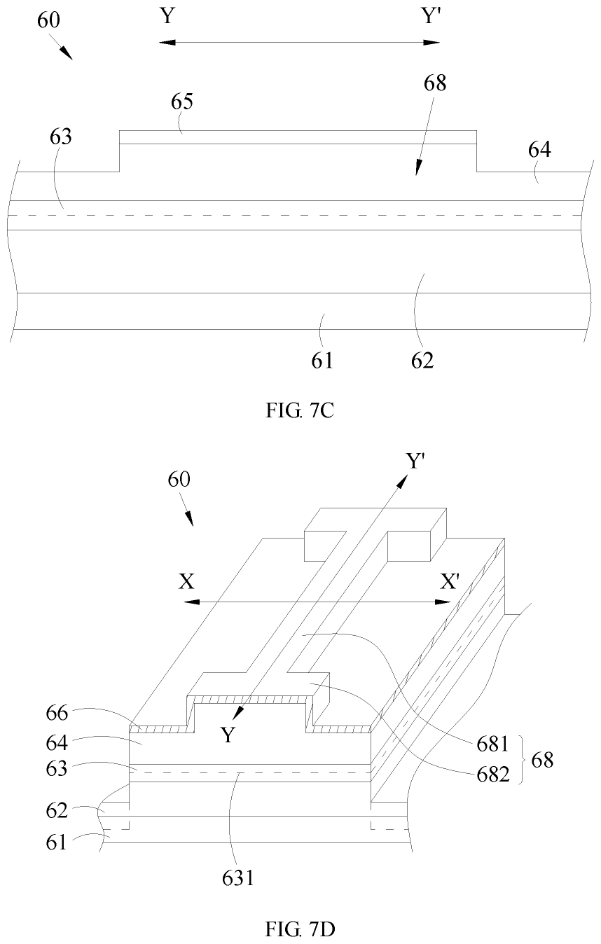

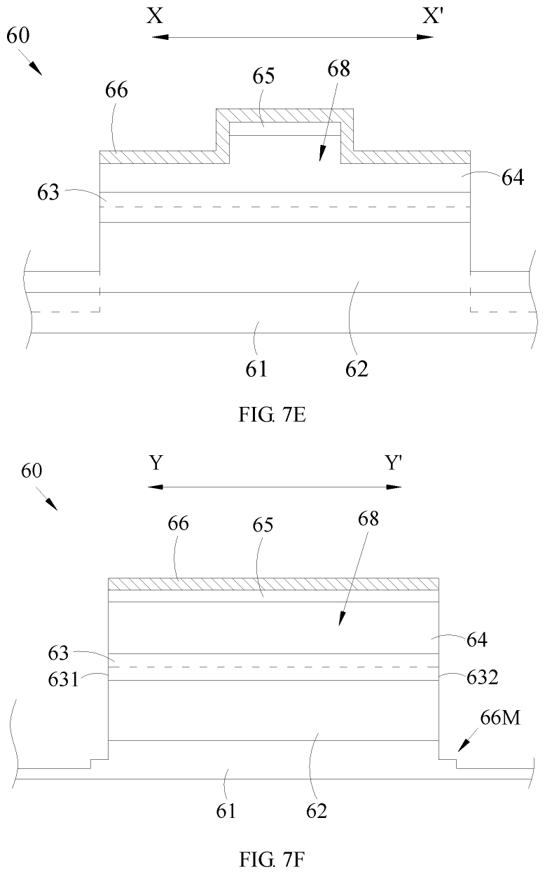

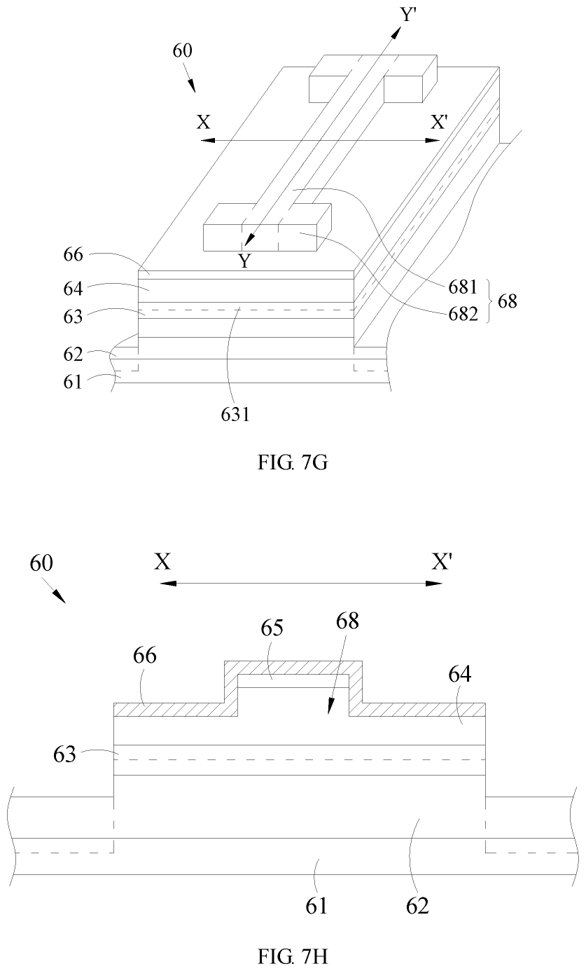

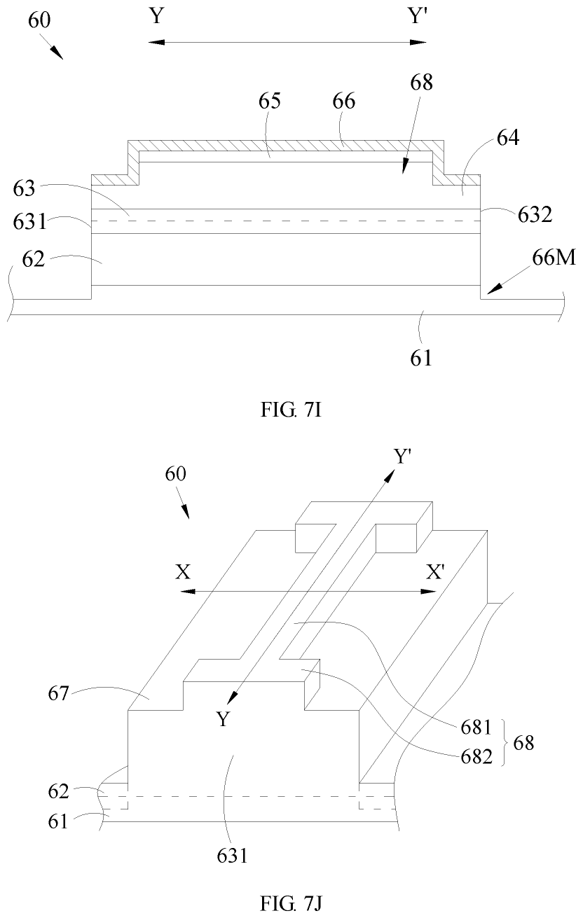

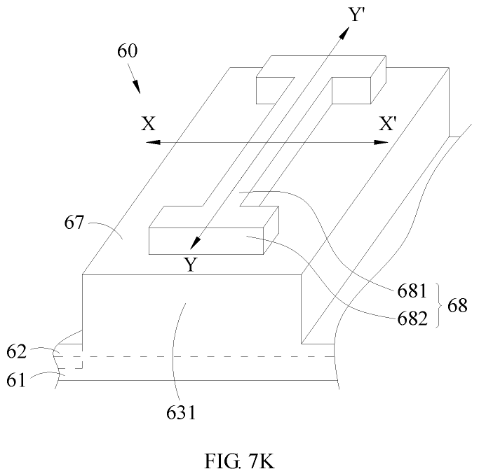

Please refer to FIG. 7A to FIG. 7K, which are schematic diagrams of the manufacturing method of the high-power edge-emitting laser device according to the first embodiment and the second embodiment of the present disclosure. Wherein, FIG. 7A is a schematic diagram of the high-power edge-emitting laser device producing the ridge waveguide, FIG. 7B is a cross-sectional schematic diagram along the direction of line segment XX′ in FIG. 7A, and FIG. 7C is a cross-sectional schematic diagram along the direction of line segment YY′ in FIG. 7A. FIG. 7D is a schematic diagram of the high-power edge-emitting laser device producing the luminous mesa and the passivation layer in the first embodiment, FIG. 7E is a cross-sectional schematic diagram along the direction of line segment XX′ in FIG. 7D, and FIG. 7F is a cross-sectional schematic diagram along the direction of line segment YY′ in FIG. 7D. FIG. 7G is a schematic diagram of the high-power edge-emitting laser device producing the luminous mesa and the passivation layer produced in the second embodiment, FIG. 7H is a cross-sectional schematic diagram along the direction of line segment XX′ in FIG. 7G, and FIG. 7I is a cross-sectional schematic diagram along the direction of line segment YY′ in FIG. 7G. FIG. 7J is a schematic diagram of the high-power edge-emitting laser device producing a dielectric layer in the first embodiment, and FIG. 7K is a schematic diagram of the high-power edge-emitting laser device producing a dielectric layer in the second embodiment.

For the manufacturing method of the high-power edge-emitting laser device, the substrate 61 is disposed firstly, and then the first cladding layer 62, the active layer 63, the second cladding layer 64, and the cap layer 65 are sequentially formed on the substrate 61. The substrate 61 may be a doped III-V compound, such as GaAs/InP/GaN. The first cladding layer 62, the active layer 63, the second cladding layer 64, and the cap layer 65 are sequentially formed on the substrate 61 through the metal-organic chemical vapor deposition (MOCVD) or a molecular beam epitaxy (MBE) machine. Wherein, the materials of the first cladding layer 62, the second cladding layer 64, and the cap layer 65 may be the same or different materials, such as AlGaAs, InP, AlₓGa_{y}InP, InGaAs, InGaAsP, Nitride (AlN), AlSb, GaAs, AlAs, GaSb, AlGaSb, or superlattice formed thereof, either as a single layer or as a combination of multi-layer materials. The active layer 63 is an active region formed of a luminescent material with a bandgap, wherein the luminescent material may include AlGaN, AlGaInP/GaAs, GaₓIn_{y}P/GaAs, GaAlAs/GaAs, GaAs/GaAs, InGaAs/GaAs, InGaAsP/GaAs, InGaAsP/InP, InGaAsSb, PbCds, GalnN, ZnSSe, ZnCdSe, PbSSe, PbSnTe, PbSnSe, or combinations thereof, either as a single layer or as a combination of multi-layer materials.

As shown in FIG. 7A to FIG. 7C, the cap layer 65 and the second cladding layer 64 are etched to form a ridge waveguide 68, wherein the ridge waveguide 68 includes a ridge column 681 formed along the first direction and an extended part 682 formed at both ends of the ridge column 681 along the second direction perpendicular to the first direction, the ridge column 681 and the extended part 682 form the ridge waveguide 68 with a T-shape structure. The disposition of the ridge waveguide 68 with a T-shape structure may avoid affecting the quality of the end face of the ridge waveguide 68 when etching is performed to form the end face such as the ridge waveguide 68 or the luminous facet 631 or the reflective plane 632 with the active layer 63.

In FIG. 7D to FIG. 7F, the ridge waveguide 68 is etched to form the luminous mesa 66M and the passivation layer 66 is disposed on the luminous mesa 66M. As shown in FIG. 7F, the ridge waveguide 68 is etched in the first direction (the Y direction as shown in the figure) at both ends up to the substrate 61, that is, etching the cap layer 65, the second cladding layer 64, the active layer 63, the first cladding layer 62, and the substrate 61 to form a luminous mesa 66M, wherein the luminous mesa 66M exposes the end face of the active layer 63 at both ends, thus defining the length of the active layer 63 in the first direction, with one end serving as the luminous facet 631. The passivation layer 66 may include dielectric materials such as oxides, fluorides, ceramics, silicon carbide, and the like, for example, silicon dioxide (SiO₂) or silicon nitride (SiₓN_{y}), and the passivation layer 66 is disposed on the luminous mesa 66M, covering the ridge waveguide 68 and the second cladding layer 64. In other embodiments, the ridge waveguide 68 may include a plurality of ridge waveguide structures disposed side by side in the second direction, and the extended parts 682 of the plurality of ridge waveguide structures are connected to each other to form an extended structure.

In the first embodiment of FIG. 7D to FIG. 7F, the length of the ridge waveguide 68 is the same as that the length of the luminescent layer 63, but the present disclosure is not limited thereto. In another embodiment, as shown in FIG. 7G to FIG. 7I, the length of the ridge waveguide 68 in the second embodiment is shorter than the length of the active layer 63. In the steps of forming the luminous mesa 66M, as shown in FIG. 7I, a luminous structure is etched in the first direction (the Y direction as shown in the figure) at both ends to the substrate 61. Since the length of the ridge waveguide 68 is shorter than the length of the active layer 63, the cap layer 65 of the ridge waveguide 68 will not be etched; instead, the second cladding layer 64, the active layer 63, the first cladding layer 62, and the substrate 61 will be etched to form a luminous mesa 66M. The luminous mesa 66M exposes the end face of the active layer 63 at both ends, thus defining the length of the active layer in the first direction, with one end serving as the luminous facet 631. The passivation layer 66 may include dielectric materials such as oxides, fluorides, ceramics, silicon carbide, and the like, for example, silicon dioxide (SiO₂) or silicon nitride (SiₓN_{y}), and the passivation layer 66 is disposed on the luminous mesa 66M, covering the ridge waveguide 68 and the second cladding layer 64.

In FIG. 7J and FIG. 7K, the dielectric layer 67 is disposed on the passivation layer 66 and the luminous facet 631, and in the following manufacturing process, a reflective plane 632 is formed at another end relative to the luminous facet 631 to form a resonant cavity between the luminous facet 631 and the reflective plane 632. The dielectric layer 67 is a thin film of dielectric material coated on the end faces of the passivation layer 66 and the active layer 63, which is used as an anti-reflective (AR coating) thin film, that is, covering the end face of the active layer 63 with an anti-reflective or low-reflective film as the luminous facet 631. Then, a metallic film with high reflectivity is formed on another end face with the use of the lift-off manufacturing process, so that another end face becomes a reflective plane 632 with high reflectivity. The active layer 63 forms a resonant cavity between the luminous facet 631 and the reflective plane 632, and when the current flows to the resonant cavity along the ridge waveguide 68, the active layer 63 may emit a laser from the luminous facet 631 in the first direction (the Y direction as shown in the figures). FIG. 7J and FIG. 7K respectively correspond to FIG. 1A of the first embodiment and FIG. 2A of the second embodiment, the same content of which shall not be described repeatedly.

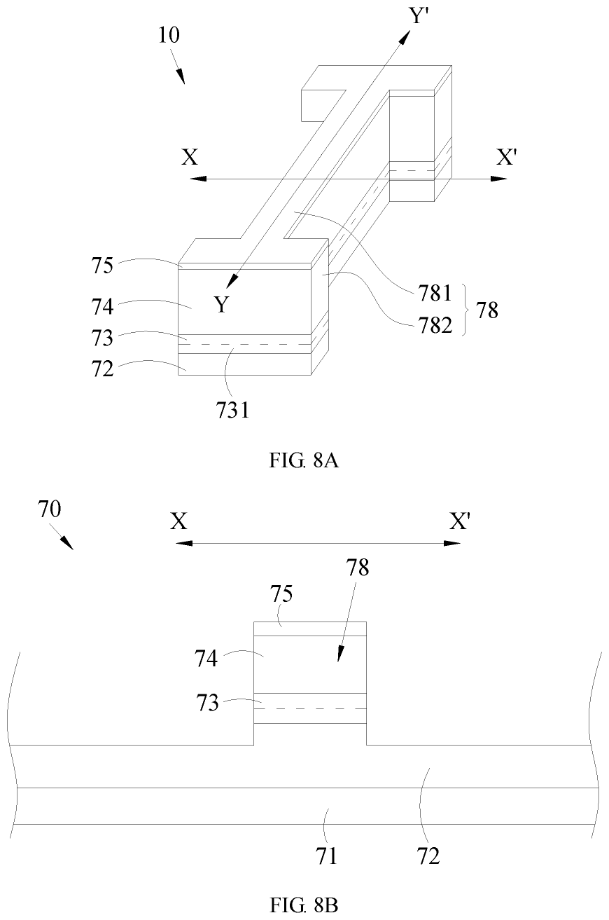

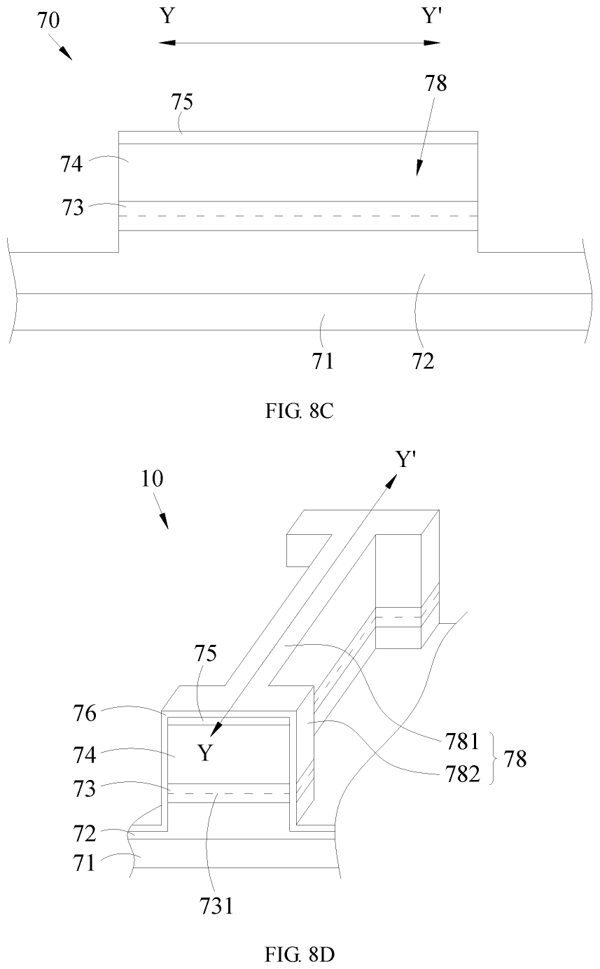

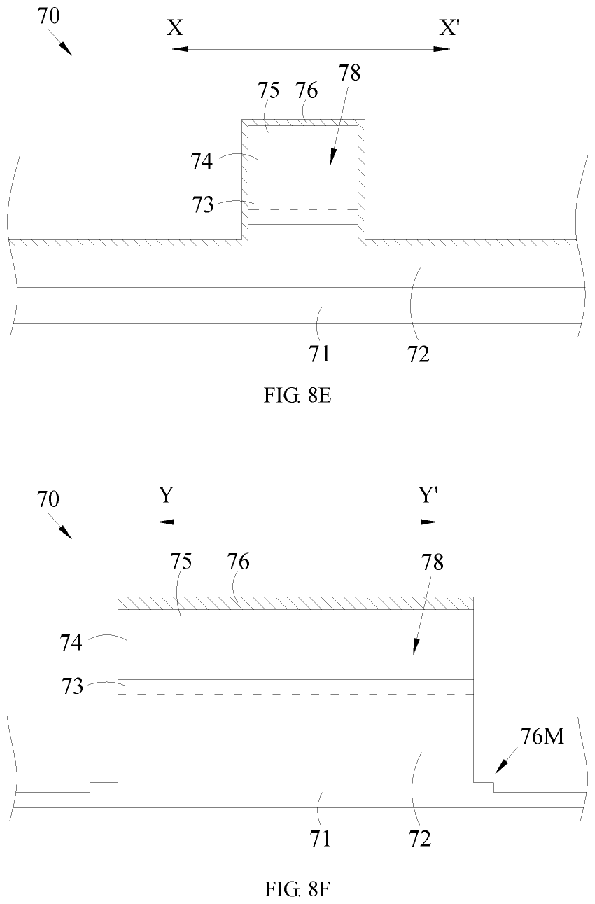

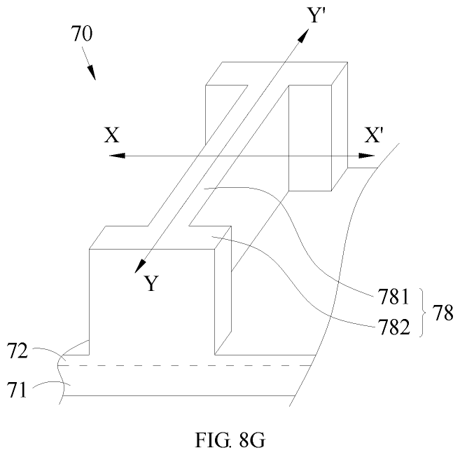

Please refer to FIG. 8A to FIG. 8G, which are schematic diagrams of the manufacturing method of the high-power edge-emitting laser device according to the third embodiment of the present disclosure. Wherein, FIG. 8A is a schematic diagram of the high-power edge-emitting laser device producing the ridge waveguide, FIG. 8B is a cross-sectional schematic diagram along the direction of line segment XX′ in FIG. 8A, and FIG. 8C is a cross-sectional schematic diagram along the direction of line segment YY′ in FIG. 8A. FIG. 8D is a schematic diagram of the high-power edge-emitting laser device producing the luminous mesa and the passivation layer in the third embodiment, FIG. 8E is a cross-sectional schematic diagram along the direction of line segment XX′ in FIG. 8D, and FIG. 8F is a cross-sectional schematic diagram along the direction of line segment YY′ in FIG. 8D. FIG. 8G is a schematic diagram of the high-power edge-emitting laser device producing the luminous mesa and the passivation layer in the third embodiment.

For the manufacturing method of the high-power edge-emitting laser device, the substrate 71 is disposed firstly, and then the first cladding layer 72, the active layer 73, the second cladding layer 74, and the cap layer 75 are sequentially formed on the substrate 71. The substrate 71 may be a doped III-V compound, such as GaAs/InP/GaN. The first cladding layer 72, the active layer 73, the second cladding layer 74, and the cap layer 75 are sequentially formed on the substrate 71 through the metal-organic chemical vapor deposition (MOCVD) or a molecular beam epitaxy (MBE) machine. Wherein, the materials of the first cladding layer 72, the second cladding layer 74, and the cap layer 75 may be the same or different materials, such as AlGaAs, InP, AlₓGa_{y}InP, InGaAs, InGaAsP, Nitride (AlN), AlSb, GaAs, AlAs, GaSb, AlGaSb, or superlattice formed thereof, either as a single layer or as a combination of multi-layer materials. The active layer 73 is an active region formed of a luminescent material with a bandgap, wherein the luminescent material may include AlGaN, AlGaInP/GaAs, GaₓIn_{y}P/GaAs, GaAlAs/GaAs, GaAs/GaAs, InGaAs/GaAs, InGaAsP/GaAs, InGaAsP/InP, InGaAsSb, PbCds, GaInN, ZnSSe, ZnCdSe, PbSSe, PbSnTe, PbSnSe, or combinations thereof, either as a single layer or as a combination of multi-layer materials.

As shown in FIG. 8A to FIG. 8C, the cap layer 75, the second cladding layer 74, the active layer 73, and the first cladding layer 72 are etched to form a ridge waveguide 78, wherein the ridge waveguide 78 includes a ridge column 781 formed along the first direction and an extended part 782 formed at both ends of the ridge column 781 along the second direction perpendicular to the first direction, the ridge column 781 and the extended part 782 form the ridge 78 waveguide with a T-shape structure. The disposition of the ridge waveguide 78 with a T-shape structure may avoid affecting the quality of the end face of the ridge waveguide 78 when etching is performed to form the end face such as the ridge waveguide 78 or the luminous facet 731 or the reflective plane 732 of the active layer 73. Different from the manufacturing method of the previous embodiment, in the present embodiment, during the manufacturing process of the ridge waveguide 78, the etching extends to the first cladding layer 72, so the structure of the ridge waveguide 78 may extend from the second cladding layer 74 to the active layer 73 and the first cladding layer 72. In another embodiment, in the manufacturing method of the ridge waveguide 78, the etching may be further extended to the substrate 71, in order to make the structure of the ridge waveguide 78 extend from the second cladding layer 74 to the active layer 73, the first cladding layer 72, and the substrate 71. The structure may be referred to in the fourth embodiment of FIG. 4A to FIG. 4C.

In FIG. 8D to FIG. 8F, the ridge waveguide 78 is etched to form the luminous mesa 76M and the passivation layer 76 is disposed on the luminous mesa 76M. As shown in FIG. 8F, the ridge waveguide 78 is etched in the first direction (the Y direction as shown in the figure) at both ends to the substrate 71, that is, etching the second cladding layer 74, the active layer 73, the first cladding layer 72, and the substrate 71 to form a luminous mesa 76M, wherein the luminous mesa 76M exposes the end face of the active layer 73 at both ends, thus defining the length of the active layer 73 in the first direction, with one end serving as the luminous facet 731. The passivation layer 76 may include dielectric materials such as oxides, fluorides, ceramics, silicon carbide, and the like, for example, silicon dioxide (SiO₂) or silicon nitride (SiₓN_{y}), and the passivation layer 76 is disposed on the luminous mesa 76M, covering the ridge waveguide 78 and the first cladding layer 72. In other embodiments, the ridge waveguide 78 may include a plurality of ridge waveguide structures disposed side by side in the second direction, and the extended part 782 of the plurality of ridge waveguide structures are connected to each other to form an extended structure.

In FIG. 8G, a dielectric layer 77 is disposed on the passivation layer 76, the luminous facet 731, and the reflective plane 732, and a reflective plane 732 is formed at another end relative to the luminous facet 731, so as to form a resonant cavity between the luminous facet 731 and the reflective plane 732. The dielectric layer 77 is a thin film of dielectric material coated on the end faces of the entire passivation layer 76 and the active layer 73, which is used as an anti-reflective (AR coating) thin film, that is, covering the end face of the active layer 73 with an anti-reflective or low-reflective film as the luminous facet 731. Then, a metallic film with high reflectivity is formed on another end face with the use of the lift-off manufacturing process, so that another end face becomes a reflective plane 732 with high reflectivity. The active layer 73 forms a resonant cavity between the luminous facet 731 and the reflective plane 732, and when the current flows to the resonant cavity along the ridge waveguide 78, the active layer 73 may emit a laser from the luminous facet 731 in the first direction (the Y direction as shown in the figure). FIG. 8G corresponds to FIG. 3A of the third embodiment, the same content of which shall not be described repeatedly.

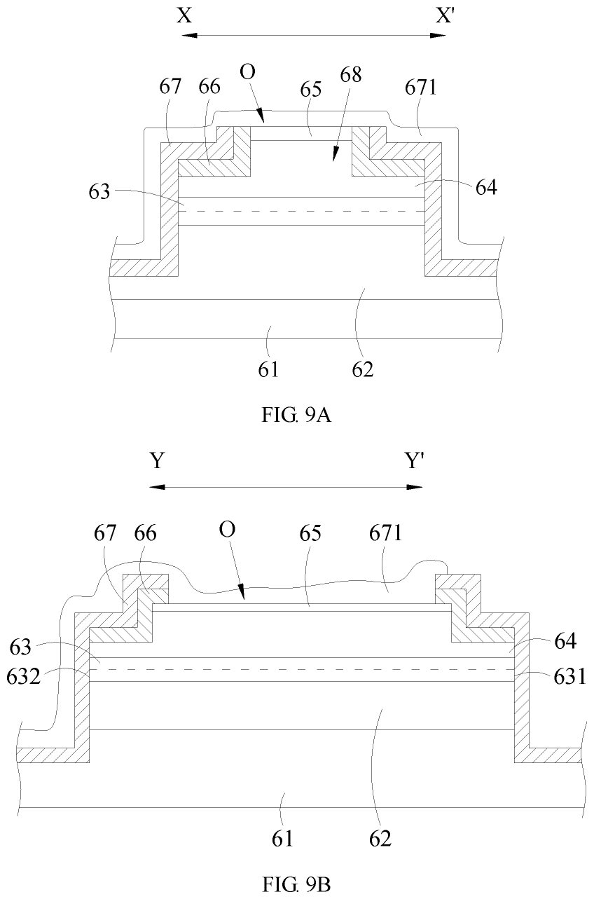

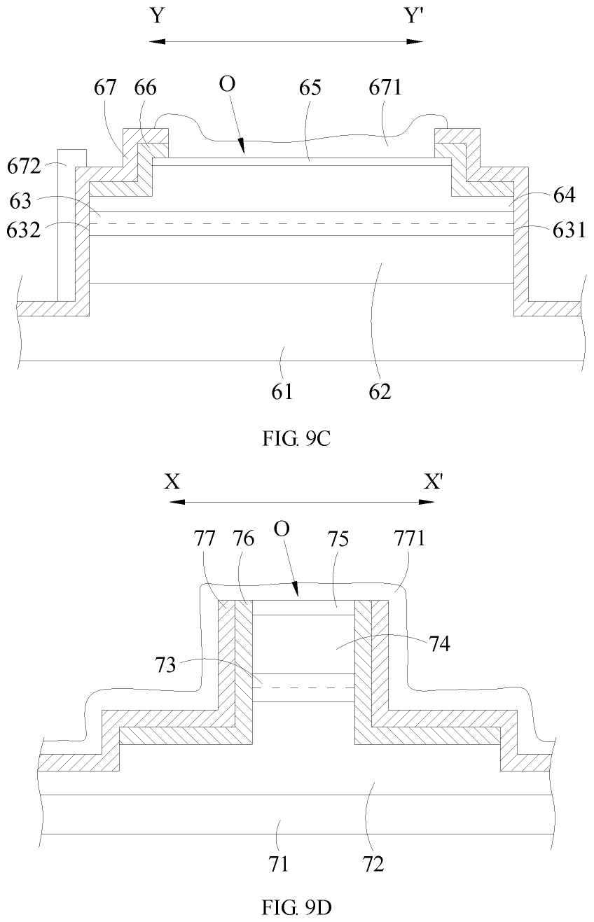

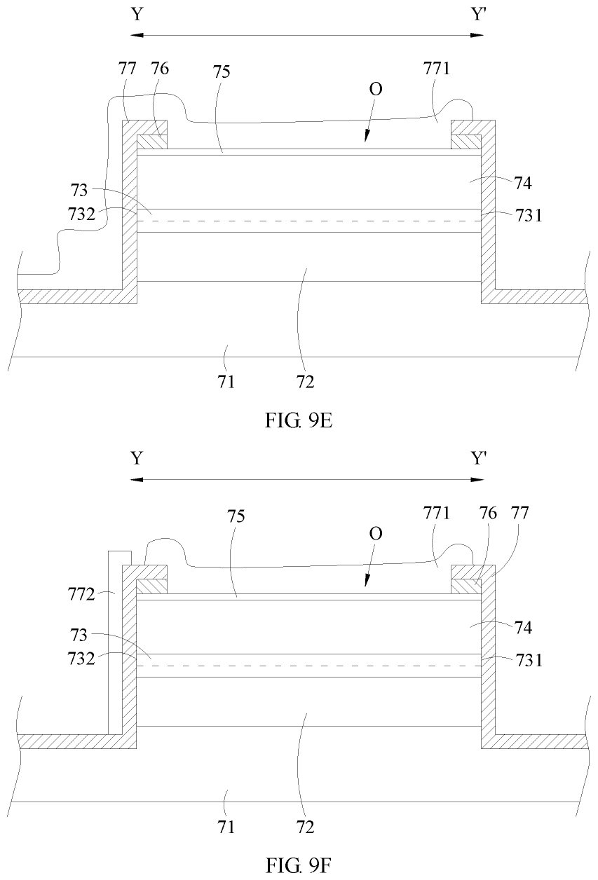

Please refer to FIG. 9A to FIG. 9F, which are schematic diagrams of the manufacturing method of metallic contact according to an embodiment of the present disclosure, wherein FIG. 9A to FIG. 9C are schematic diagrams continuing from FIG. 7K in the second embodiment, and FIG. 9D to FIG. 9F are schematic diagrams continuing from FIG. 8G in the third embodiment. In FIG. 9A and FIG. 9B, the dielectric layer 67 is an anti-reflective (AR coating) film on the end faces of the passivation layer 66 and the active layer 63, that is, covering the end face of the active layer 63 with an anti-reflective or low-reflective film as the luminous facet 631. Next, the cap layer 65 is exposed by making an opening O, the first metallic film 671 is coated on the opening O and the dielectric layer 67 as metallic contact, and another end face of the luminous facet 631 becomes a reflective plane 632 with high reflectivity. The active layer 63 forms a resonant cavity between the luminous facet 631 and the reflective plane 632, and when the current flows to the resonant cavity along the ridge waveguide, the active layer 63 may emit a laser from the luminous facet 631.

In FIG. 9C, the dielectric layer 67 is an anti-reflective (AR coating) film on the end faces of the passivation layer 66 and the active layer 63, that is, covering the end face of the active layer 63 with an anti-reflective or low-reflective film as the luminous facet 631. What is different from FIG. 9B is that on another end surface opposite to the luminous facet 631, the second metallic film 672 is first made to cover the end face to form a reflective plane 632 with high reflectivity; then, the cap layer 65 is exposed by making an opening O, and the first metallic film 671 is coated on the opening O and the dielectric layer 67 as metallic contact. The active layer 63 also forms a resonant cavity between the luminous facet 631 and the reflective plane 632, and when the current flows to the resonant cavity along the ridge waveguide, the active layer 63 may emit a laser from the luminous facet 631 in the first direction. In the present embodiment, the first metallic film 671 does not cover the second metallic film 672, but in other embodiments, the first metallic film 671 may also cover the second metallic film 672.

In FIG. 9D and FIG. 9E, the dielectric layer 77 is used as an anti-reflective (AR coating) film on the end faces of the passivation layer 76 and the active layer 73, that is, covering the end face of the active layer 73 with an anti-reflective or low-reflective film as the luminous facet 731. Next, the cap layer 75 is exposed by making an opening O, the metallic film 771 is coated on the opening O and the dielectric layer 77 as metallic contact, and another end face of the luminous facet 731 becomes a reflective plane 732 with high reflectivity. The active layer 73 forms a resonant cavity between the luminous facet 731 and the reflective plane 732, and when the current flows to the resonant cavity along the ridge waveguide, the active layer 73 may emit a laser from the luminous facet 731.

In FIG. 9F, the dielectric layer 77 is used as an anti-reflective (AR coating) film on the end faces of the passivation layer 76 and the active layer 73, that is, covering the end face of the active layer 73 with an anti-reflective or low-reflective film as the luminous facet 731. What is different from FIG. 9E is that on another end surface opposite to the luminous facet 731, the second metallic film 772 is firstly made to cover the end face to form a reflective plane 732 with high reflectivity; then, the cap layer 75 is exposed by making an opening O, and the first metallic film 771 is coated on the opening O and the dielectric layer 77 as metallic contact. The active layer 73 also forms a resonant cavity between the luminous facet 731 and the reflective plane 732, and when the current flows to the resonant cavity along the ridge waveguide, the active layer 73 may emit a laser from the luminous facet 731. In the present embodiment, the first metallic film 771 does not cover the second metallic film 772, but in other embodiments, the first metallic film 771 may also cover the second metallic film 772.

Please refer to FIG. 5A and FIG. 5B, the manufacturing method of the high-power edge-emitting laser device may further form a reflective bevel A by etching the first cladding layer 42, the active layer 43, and the second cladding layer 44 with a mask having a predetermined slope, and form a reflected metal layer 49 on the reflective bevel A, wherein a bevel of the reflected metal layer 49 faces the luminous facet 431, the laser R emitted from the luminous facet 431 may be changed from the horizontal direction to the vertical direction after being reflected by the reflected metal layer 49, and the original edge-emitting laser R is changed to a surface-emitting laser R without significantly changing the semiconductor package structure. The metallic material of the reflected metal layer 49 may include Ti/Al, Cr/Al, Cr/Au, Ni/Al, Ni/Au, AuGe/Au, or AuGe/Ni/Au.

Since the laser beam has a certain divergent angle, the closer the reflective plane of the reflected metal layer 49 is to the luminous facet 431, or the lower the position of the active layer 43, the greater the light power may be deflected. In the present embodiment, there is a horizontal distance D between the top of the reflected metal layer 49 and the luminous facet 431, and the horizontal distance D may be less than 12 times the depth of the active layer 43 (that is, the distance from the wafer surface to the active layer 43). In addition, the width of the reflected metal layer 49 needs to be larger than that the width of the ridge waveguide in order to obtain sufficient optical power transition. To further increase the optical power, the height 491 of the reflected metal layer 49 may be increased, so that the height of the top of the reflected metal layer 49 is higher than that the height of the luminous facet 431. In the etching process, the groove 492 is formed between the bevel A of the reflected metal layer 49 and the luminous facet 431, the groove 492 may trap part of the laser R that is emitted obliquely downward at a larger angle, and in a sensing application where laser R is used as a light source, noise may be reduced and the signal-to-noise ratio (SNR) may be increased.

The above description is merely illustrative rather than restrictive. Any equivalent modifications or alterations without departing from the spirit and scope of the present disclosure are intended to be included in the following claims.

What is claimed is:

1. A high-power edge-emitting laser device, comprising:
a substrate;
a first cladding layer disposed on the substrate;
an active layer disposed on the first cladding layer;
a second cladding layer disposed on the active layer;
a cap layer disposed on the second cladding layer, the cap layer and the second cladding layer having a ridge waveguide, wherein the ridge waveguide comprises a ridge column disposed along a first direction and an extended part disposed along a second direction perpendicular to the first direction at both ends of the ridge column, the ridge column and the extended part form a T-shape structure, so that a width of the ridge waveguide at the extended part is greater than a width of the ridge waveguide at the ridge column;
a passivation layer disposed on a luminous mesa, the luminous mesa defining a length of the active layer in the first direction, and one side of the luminous mesa exposing a luminous facet of the active layer; and
a dielectric layer disposed on the passivation layer and covering the luminous facet, a reflective plane being disposed at another end relative to the luminous facet, so that the active layer forms a resonant cavity between the luminous facet and the reflective plane, and a laser is emitted from the luminous facet.

2. The high-power edge-emitting laser device according to claim 1, wherein the ridge waveguide extends from the second cladding layer to the active layer and the first cladding layer.

3. The high-power edge-emitting laser device according to claim 1, wherein the ridge waveguide extends from the second cladding layer to the active layer, the first cladding layer, and the substrate.

4. The high-power edge-emitting laser device according to claim 1, wherein in the first direction, a length of the ridge waveguide is less than or equal to a length of the active layer.

5. The high-power edge-emitting laser device according to claim 1, wherein the ridge waveguide comprises a plurality of ridge waveguide structures disposed side by side in the second direction, and the extended parts of the plurality of ridge waveguide structures are connected to each other to form an extended structure.

6. The high-power edge-emitting laser device according to claim 1, further comprising a reflected metal layer disposed on a reflector made by etching an epitaxy and the substrate, wherein a bevel of the reflected metal layer faces the luminous facet, and there is a horizontal distance between a top of the reflected metal layer and the luminous facet.

7. The high-power edge-emitting laser device according to claim 6, wherein a height of the top of the reflected metal layer is higher than a height of the luminous facet, and the horizontal distance is less than 12 times a depth of the active layer.

8. The high-power edge-emitting laser device according to claim 6, wherein a groove is disposed between the bevel of the reflected metal layer and the luminous facet.

9. The high-power edge-emitting laser device according to claim 6, wherein the reflected metal layer comprises Ti/Al, Cr/Al, Cr/Au, Ni/Al, Ni/Au, AuGe/Au, or AuGe/Ni/Au.

10. The high-power edge-emitting laser device according to claim 1, further comprising a metallic film, wherein the metallic film is disposed on part of the dielectric layer and covers the reflective plane, the metallic film contacts the cap layer through an opening.

11. The high-power edge-emitting laser device according to claim 10, wherein the metallic film comprises Ti/Au, Ti/Al, Cr/Al, Cr/Au, Ni/Al, Ni/Au, or Au.

12. A manufacturing method of a high-power edge-emitting laser device, comprising following steps:
disposing a substrate and sequentially forming a first cladding layer, an active layer, a second cladding layer, and a cap layer on the substrate;
etching the cap layer and the second cladding layer to form a ridge waveguide, wherein the ridge waveguide comprises a ridge column formed along a first direction and an extended part formed at both ends of the ridge column along a second direction perpendicular to the first direction, the ridge column and the extended part form a T-shape structure;
etching the ridge waveguide to form a luminous mesa and disposing a passivation layer on the luminous mesa, the luminous mesa defining a length of the active layer in the first direction, and the luminous mesa exposes a luminous facet of the active layer;
disposing a dielectric layer on the passivation layer and the luminous facet and forming a reflective plane at another end relative to the luminous facet, wherein a resonant cavity is formed between the luminous facet and the reflective plane.

13. The manufacturing method of the high-power edge-emitting laser device according to claim 12, wherein the active layer and the first cladding layer are further etched when the cap layer and the second cladding layer are etched, so that the ridge waveguide extends from the second cladding layer to the active layer and the first cladding layer.

14. The manufacturing method of the high-power edge-emitting laser device according to claim 12, wherein the active layer, the first cladding layer, and the substrate are further etched when the cap layer and the second cladding layer are etched, so that the ridge waveguide extends from the second cladding layer to the active layer, the first cladding layer, and the substrate.

15. The manufacturing method of the high-power edge-emitting laser device according to claim 12, wherein in the first direction, a length of the ridge waveguide is less than or equal to a length of the active layer.

16. The manufacturing method of the high-power edge-emitting laser device according to claim 12, wherein the ridge waveguide comprises a plurality of ridge waveguide structures disposed side by side in the second direction, and the extended parts of the plurality of ridge waveguide structures are connected to each other to form an extended structure.

17. The manufacturing method of the high-power edge-emitting laser device according to claim 12, further forming a reflective bevel by etching the first cladding layer, the active layer, the second cladding layer, and the substrate with a mask having a predetermined slope, and forming a reflected metal layer on the reflective bevel, wherein a bevel of the reflected metal layer faces the luminous facet, and there is a horizontal distance between a top of the reflected metal layer and the luminous facet.

18. The manufacturing method of the high-power edge-emitting laser device according to claim 17, wherein a height of the top of the reflected metal layer is higher than a height of the luminous facet, and the horizontal distance is less than 12 times a depth of the active layer.

19. The manufacturing method of the high-power edge-emitting laser device according to claim 17, wherein a groove is formed between a bevel of the reflected metal layer and the luminous facet.

20. The manufacturing method of the high-power edge-emitting laser device according to claim 17, wherein the reflected metal layer comprises Ti/Al, Cr/Al, Cr/Au, Ni/Al, Ni/Au, AuGe/Au, or AuGe/Ni/Au.

21. The manufacturing method of the high-power edge-emitting laser device according to claim 12, further etching the passivation layer and the dielectric layer to form an opening, wherein the opening exposes the cap layer, and a metallic film is disposed on part of the dielectric layer and covers the reflective plane, the metallic film contacts the cap layer through the opening.

22. The manufacturing method of the high-power edge-emitting laser device according to claim 21, wherein the metallic film comprises Ti/Au, Ti/Al, Cr/Al, Cr/Au, Ni/Al, Ni/Au, or Au.
